(19) United States
(12) Patent Application Publication
(10) Pub. No.: US 2010/0244872 A1
(43) Pub. Date: Sep. 30, 2010

(54) INSPECTION SOCKET AND METHOD OF PRODUCING THE SAME

(76) Inventors: Takuto Yoshida, Tokyo (JP); Satoshi Kakegawa, Gunma (JP)

Correspondence Address: MORGAN LEWIS & BOCKIUS LLP, 1111 PENNSYLVANIA AVENUE NW, WASHINGTON, DC, 20004, US

(21) Appl. No.: 12/750,018

(22) Filed: Mar. 30, 2010

(30) Foreign Application Priority Data
Mar. 31, 2009 (JP) P.2009-087212

(51) Int. Cl. G01R 31/02

(52) U.S. Cl. 324/755

(57) ABSTRACT

An inspection socket configured to connect an electrode terminal of an object to be inspected and a wiring of a wiring board, includes: a metal block including a first surface to be opposed to the object to be inspected and a second surface to be opposed to the wiring board, and provided with a through hole connecting the first surface and the second surface in a first direction, an inner wall of the through hole having a part which is not rectilinear in the first direction; and a contact probe for grounding provided in the through hole, and being connected to the inner wall of the through hole, at least in vicinity of the part which is not rectilinear.

### BACKGROUND OF THE INVENTION

The present invention relates to an inspection socket for reliably bringing electrode terminals of an object to be inspected into contact with a wiring board which is connected to an inspection device, on occasion of inspecting an LSI (a large scale integrated circuit) including a monolithic IC and a hybrid IC, or a module component obtained by combining discrete components such as a plurality of ICs and LCRs into hybrid thereby to realize desired functions (hereinafter, all of them are referred to simply as an IC or an object to be inspected), and a method of producing the same. More particularly, in the inspection socket for inspecting the object to be inspected for high frequency and high speed (high frequency in analogue form is referred to as the high frequency, while very short pulse width and short pulse interval in digital form are referred to as the high speed, both of which are hereinafter referred to as an RF), it is also necessary to reliably connect the grounding terminal to the ground (earth) in vicinity of the terminal for RF signals, and a probe for grounding is also provided in the inspection socket. The invention relates to the inspection socket which is so constructed as to reliably connect the probe for grounding to the ground, and a method of producing the same.

In the IC which has been highly integrated and highly functioned in recent years, it is necessary to inspect its performance, before the IC is actually incorporated into a circuit. In case of inspecting such IC or the like, the electrode terminals of the IC or the like must be reliably brought into contact with wiring terminals of a wiring board on which wirings connected to an inspection device are formed, without soldering or so. For this purpose, as shown in FIG. 5A, for example, an inspection socket 1 is interposed between a wiring board 2 and the object to be inspected such as an IC 3 thereby to conduct an inspection. FIG. 5B is an enlarged explanatory view showing a part including a contact probe 12GND for grounding.

In an example as shown in FIGS. 5A and 5B, this inspection socket 1 is so constructed that contact probes 12 are inserted into through holes which are provided in a metal block 11, and insulating boards 13 called as pressing plates are fixed to both upper and lower surfaces of the metal block 11 with screws, which are not shown, so that the contact probes 12 may not escape from the metal block 11. The contact probes 12 includes contact probes 12S for RF signals, contact probes 12P for low frequency signals or power supply, contact probes 12GND for grounding (earth). These contact probes 12 are provided so as to correspond to respective terminals 31 of the IC 3.

By employing the metal block 11 as described above, not only intrusion of noise into the contact probes 12 can be easily prevented, but also, a case where a pitch of electrode terminals has become very small due to recent tendency of becoming high integrated can be easily dealt with, while the contact probe 12S for RF signals is formed in a coaxial structure. Moreover, it is advantageous that the contact probe 12GND for grounding can be easily connected to the ground, by directly bringing it into contact with the metal block 11.

However, it is difficult to insert the contact probe 12GND for grounding into the through hole in the metal block 11, and to obtain reliable electrical connection directly with respect to the metal block 11. It has been attempted to obtain reliable electrical connection between the contact probe 12GND for grounding and the metal block 11, by employing a method in which a ground tube 18 is inserted between the contact probe 12GND for grounding and the metal block 11, and a projection 18a is formed on the ground tube 18, thereby to obtain reliable contact between the ground tube 18 and the contact probe 12GND for grounding, as shown in an enlarged explanatory sectional view of the contact probe 12GND for grounding in FIG. 5B (refer to JP-A-2005-49163), and a method in which the ground tube 18 is provided with a cut 18b, and made taper in a longitudinal direction, for reliably bringing a thinner part of the ground tube 18 into contact with the contact probe 12GND for grounding, while a thicker part of the ground tube 18 can be easily contacted with an inner wall of the through hole in the metal block, as shown in FIGS. 6A and 6B.

In case where reliable electrical connection between the ground tube and the contact probe for grounding is attained by inserting the ground tube into the contact probe for grounding and by forming the projection, and thereafter, the ground tube is inserted into the through hole in the metal block, or alternatively, in case where the ground tube in a taper shape having the cut is inserted into the contact probe for grounding, and thereafter, the ground tube is inserted into the through hole in the metal block, as described above, it is necessary that at least a part of the ground tube has a larger diameter than an inner diameter of the through hole, for enabling the ground tube having the contact probe for grounding inserted therein to be inserted into the through hole. Therefore, it is extremely difficult to insert the very small contact probe for grounding having a length of about 3 to 10 mm and a thickness of about 0.3 mm into the through hole, and assembling steps are increased. Besides, a cost for the ground tube itself is incurred, and there is a problem that a considerable increase of cost is inevitable.

### SUMMARY

It is therefore an object of the invention to provide an inspection socket which can be easily assembled, having reduced number of components, and can reliably achieve electrical connection between a contact probe for grounding and an inner wall of a metal block, and a method of producing the same.

In order to achieve the object, according to the invention, there is provided an inspection socket configured to connect an electrode terminal of an object to be inspected and a wiring of a wiring board, the inspection socket comprising:

a metal block including a first surface to be opposed to the object to be inspected and a second surface to be opposed to the wiring board, the metal block provided with a through hole connecting the first surface and the second surface in a first direction, an inner wall of the through hole having a part which is not rectilinear in the first direction; and

a contact probe for grounding provided in the through hole, the contact probe for grounding being connected to the inner wall of the through hole, at least in vicinity of the part which is not rectilinear.

The contact probe for grounding may be bent by the part which is not rectilinear, whereby the contact probe for grounding is directly and electrically connected to the inner wall of the through hole, at least in vicinity of the part which is not rectilinear.

The inspection socket may further include a securing member securing the contact probe for grounding so as not to escape from the through hole.

The through hole may be formed in an L-shape in a sectional view in the first direction.

A center position of the through hole at one end on the first surface of the metal block and a center position of the through hole at an inside in the first direction may be offset in a second direction perpendicular to the first direction.

The metal block may have a first layer, a second layer and a third layer which is disposed between the first layer and the second layer, the first layer may include a first hole, the second layer may include a second hole and the third layer may include a third hole. The through hole may be defined by the first hole, the second hole and the third hole. An inner diameter of the third hole may be smaller than an inner diameter of the first hole and an inner diameter of the second hole, and the third hole may be offset from at least one of the second hole and the first hole.

In order to achieve the object, according to the invention, there is also provided a method of producing an inspection socket, the method comprising:

preparing a metal block having a first layer, a second layer and a third layer which is disposed between the first layer and the second layer, the first layer including a first hole, the second layer including a second hole, the third layer including a third hole, a through hole being defined by the first hole, the second hole and the third hole in a state where the first layer, the second layer and the third layer are superposed;

inserting a contact probe for grounding into the through hole; and

displacing the third layer so that the third hole is offset from at least one of the second hole and the first hole.

In order to achieve the object, according to the invention, there is also provided an inspection socket configured to connect an object to be inspected and a wiring board, the inspection socket comprising:

a metal block including a first surface to be opposed to the object to be inspected and a second surface to be opposed to the wiring board, the metal block provided with a through hole connecting the first surface and the second surface, an inner wall of the through hole having:
a first portion extending in a first direction;
a second portion extending in a second direction different from the first direction; and
a third portion connecting the first portion and the second portion; and

a contact probe for grounding provided in the through hole, a part of the contact probe being in contact with the third portion.

### BRIEF DESCRIPTION OF THE DRAWINGS

FIGS. 1A and 1B are explanatory sectional views respectively showing an inspection socket in an embodiment according to the invention, and FIG. 1C shows an example of a contact probe which is used in the inspection socket.

FIGS. 2A, 2B and 2C are explanatory views showing the contact probe for grounding in the inspection socket and a through hole in another embodiment according to the invention.

FIGS. 3A, 3B and 3C are explanatory views showing the contact probe for grounding in the inspection socket and a through hole in still another embodiment according to the invention.

FIGS. 4A and 4B are explanatory views for explaining a method of assembling the inspection socket according to the invention as shown in FIGS. 3A to 3C.

FIGS. 5A and 5B are explanatory views showing an example of a related-art inspection socket, and a contact probe for grounding.

FIGS. 6A and 6B are explanatory views showing another related-art example of a ground tube for securing reliable electrical connection between a contact probe for grounding and a through hole.

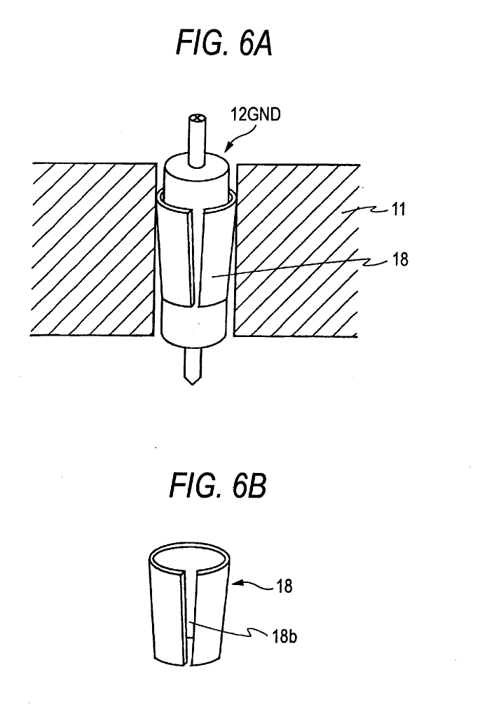

### DETAILED DESCRIPTION OF EMBODIMENTS

Now, an inspection socket and a method of producing the same according to the invention will be described, referring to the drawings.

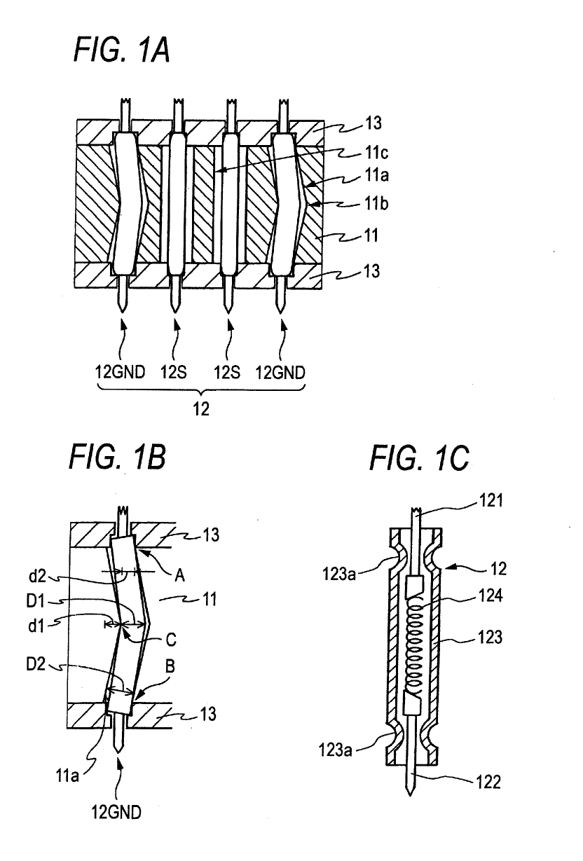

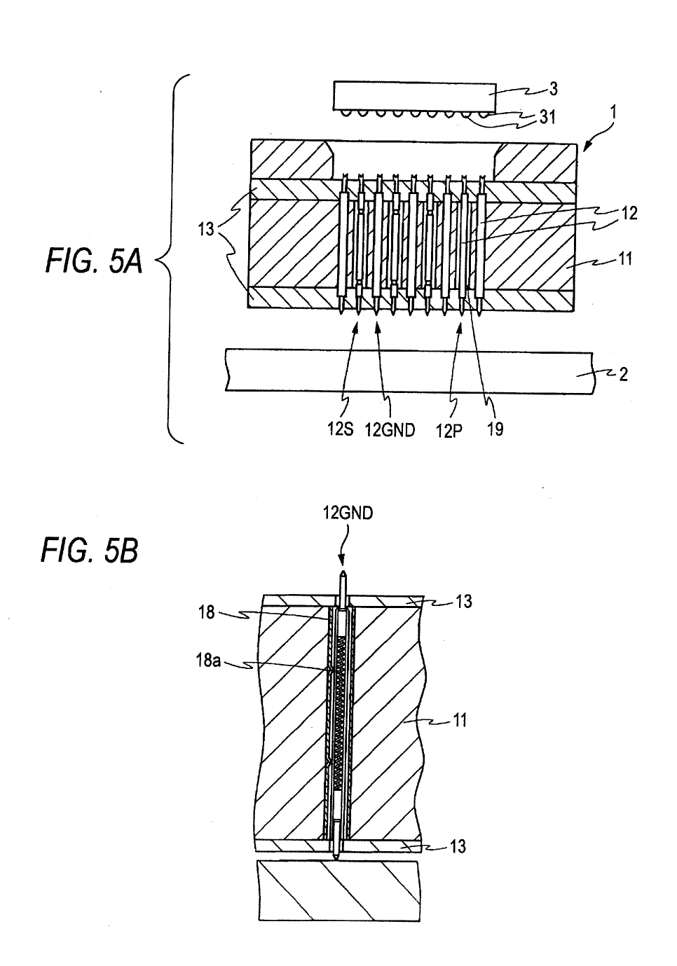

The inspection socket according to an aspect of the invention is intended to connect electrode terminals of an object to be inspected such as an IC to wirings of a wiring board, as shown partly in section in FIGS. 1A and 1B (an entire structure is the same as the structure as shown in FIG. 5A). A metal block 11 is provided with a plurality of through holes 11a, 11c passing it through in a direction of its thickness, and contact probes 12 including at least contact probes 12GND for grounding are contained in the through holes 11a, 11c in the metal block 11. The contact probes 12 are secured by securing members including, for example, insulating boards 13 such as pressing plates so as not to escape from the through holes 11a, 11c. An inner wall of the though hole 11a into which this contact probe 12GND for grounding is inserted is not rectilinear in an axial direction, but has a discontinued part 11b, so that the contact probe 12GND for grounding can be electrically connected to the inner wall of the through hole 11a directly at least in vicinity of this discontinued part 11b.

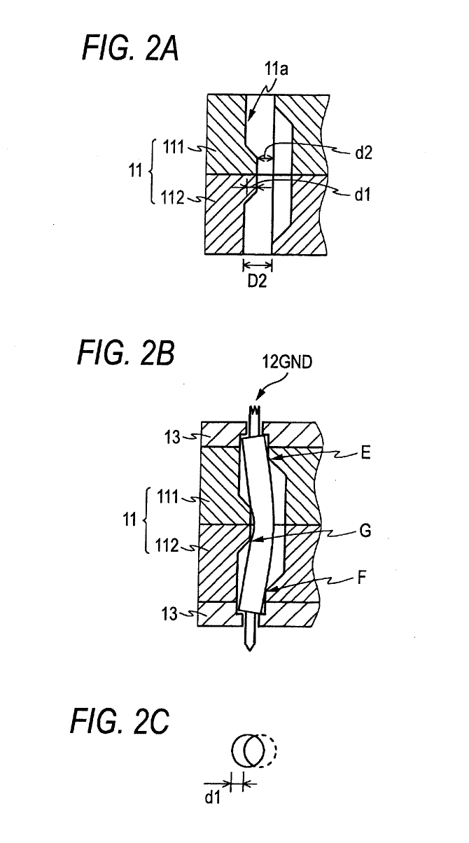

The metal block 11 holds the contact probes 12 for signal terminals, for power supply terminals or for grounding terminals and so on to be brought into contact with electrode terminals of the object to be inspected such as an IC. In case where the contact probe 12S for RF signals to be connected to a terminal for RF signals is formed in a coaxial structure, by using a metallic substance such as brass, aluminum, etc. for example, matching of impedance can be obtained with a small sectional area, by making an inner wall of the through hole 11c into which the contact probe 12S for RF signals is inserted as an external conductor, and by making the contact probe 12S for RF signals as a center conductor (an internal conductor). Moreover, in case of the contact probe for signal terminal or power supply terminal (not shown) which is not the contact probe for RF signals, the contact probe is fixed in the through hole 11c interposing an insulating tube or the like so as not to come into contact with the metal block 11. In case of the contact probe for grounding terminal, the inner wall of the through hole 11a is not rectilinear in the axial direction, but formed as having the discontinued part 11b so as to be reliably brought into contact with the metal block 11. Usually, this metal block 11 has a thickness of about 3 to 8 mm, and an area of 30 to 50 mm square. Although the metal block 11 is formed as an integral body of metal in a plate-like shape in an embodiment as shown in FIG. 1A, it is also possible to form the metal block 11 in a shape of two or more layers of plate-like metal superposed in the same manner as in another embodiment as shown in FIGS. 2A to 2C and to integrally fix them with screws which are not shown.

In the embodiment as shown in FIGS. 1A and 1B, the through hole 11a into which the contact probe 12GND for grounding is inserted is formed in an L-shape in a sectional view. As dimensional relation is shown in FIG. 1B, a distance (an offset amount) d1 between upper and lower end faces of the metal block 11 having a thickness of about 3.5 mm and a swelled part at a center part of the through hole 11a is about 0.1 mm, and a distance d2 between the swelled part at the center part of the through hole 11a in the metal block 11 and the inner wall of the through hole at the upper and lower end faces of the metal block 11 (that is, a diameter of a part vertically passing through the metal block 11) is about φ0.25 mm. An outer diameter D1 of the contact probe 12GND for grounding is about φ0.3 mm, while an inner diameter of the through hole 11a, that is, an inner diameter D2 of the though hole 11a at the upper and lower surfaces of the metal block 11 is about φ0.35 mm. Therefore, in case where the contact probe 12GND for grounding having the diameter of about φ0.3 mm is inserted into the through hole 11a, it is impossible to rectilinearly insert the contact probe 12GND for grounding, since the inner diameter d2 of the rectilinear part of the through hole 11a is about φ0.25 mm. However, by pushing the contact probe 12GND for grounding diagonally according to the shape of the through hole 11a, the contact probe 12GND for grounding is pushed in along the L-shape of the through hole 11a, and the contact probe 12GND for grounding itself is deformed into an L-shape.

Even though the contact probe 12GND for grounding is forcibly inserted into the through hole 11a in this manner, it is possible to insert it in an L-shape, because a difference between their diameters is only about 0.05 mm, and there is a sufficient room in a diagonal direction, and further, because the contact probe 12 is so constructed that a spring is inserted into a soft metal pipe formed of, for example, nickel silver (an alloy of copper, nickel and zinc), as described below. Moreover, it is only necessary for the contact probe 12GND for grounding that a plunger at a distal end thereof can be freely moved by a spring to obtain electrical connection, while the outer diameter of the contact probe 12GND for grounding is not important unlike the contact probe 12S for RF signals. Therefore, no problem occurs even though the contact probe 12GND for grounding is somewhat deformed.

By being constructed in this manner, the contact probe 12GND for grounding is slightly bent (the bending is exaggerated in FIGS. 1A and 1B), and in a state as shown in FIG. 1B, a center part of the contact probe 12GND for grounding is pressed against the swelled part C in the through hole 11a of the metal block 11. Upper and lower end parts of the contact probe 12GND for grounding are pressed against both faces (corner parts on a surface and a back face) of the metal block 11 at an opposite side to the swelled part of the metal block 11 (a right side in FIG. 1B). As the results, the contact probe 12GND for grounding and the metal block 11 come into reliably contact with each other, at two positions, namely, right side faces A and B of both upper and lower faces and at the swelled part C at the center part of the metal block 11, as shown in FIG. 1B, and hence, reliable electrical connection can be obtained.

The contact probe 12 is so constructed that a spring 124 and respective distal ends of plungers (movable pin) 121, 122 are contained in a metal pipe 123, as shown by the sectional explanatory view in FIG. 1C, for example, and the plungers 121, 122 are held so as not to escape from the metal pipe 123 by means of dented parts 123a which are provided in the metal pipe 123, and at the same time, urged outward by the spring 124. When the distal ends of the plungers 121, 122 are pressed, the spring 124 is contracted, and the distal ends are pushed into the metal pipe 123. When a force is not applied, the distal ends of the plungers 121, 122 are projected. A moving amount of the plungers is about 0.3 mm at one side. The probe 120 is designed in such a manner that an appropriate spring pressure can be obtained and reliability is most enhanced, when its total length is reduced by about 0.6 mm by the movements of the two plungers 121, 122 at both upper and lower sides. The metal pipe 123 is formed of nickel silver (an alloy of copper, nickel and zinc), for example, and has a length of about a few millimeters. As the plungers 121, 122, a wire material formed of SK material or beryllium copper and having a diameter of about 0.1 mm is used. The spring 124 is formed of a piano wire or the like.

A mounting structure of the contact probe 12S for RF signals is the same as the conventional structure, and detailed description of the structure is omitted. An outer diameter of this contact probe 12S and an inner diameter of the through hole 11c are so formed as to have a determined impedance respectively as the diameter of an internal conductor and as the inner diameter of an external conductor of a coaxial structure. In this case, a hollow space is formed so as to have a small dielectric constant between the contact probe 12S and the through hole 11c so that the inner diameter of the through hole 11c can be as small as possible.

The insulating board 13 is a so-called pressing plate, and it would be preferable to use the insulating board formed of resin such as polyether imide (PEI), for example, because the recesses 13b and the through holes 13a can be formed more easily by resin molding at accurate sizes, even in case where a number of the contact probes 12 are arranged in parallel at a narrow pitch. Moreover, the above described resin has a large mechanical strength, and therefore, in case where the insulating board 13 has a thickness of about 1 mm, the insulating board 13 will not be deflected and can stably hold the contact probes even in case where several hundreds or more contact probes are provided. However, any other material may be used, provided that the material is electrically insulating, thin, and has a sufficient mechanical strength.

FIGS. 2A and 2B are explanatory views showing the through hole 11a and the contact probe 12GND for grounding in another embodiment of the invention, which are similar to those in FIG. 1B. In this embodiment, the metal block 11 is divided in two layers into a first metal block (a first layer) 111, and a second metal block (a second layer) 112, and they are integrally fixed with screws which are not shown. In this embodiment, a position of the through hole 11a is displaced, as shown in FIG. 2C, between outer faces and joint faces of the respective metal blocks 111 and 112. An amount of this displacement (an offset amount) d1 is about 0.1 mm, which is the same as described in FIGS. 1A and 1B. Specifically, the through hole 11a itself is formed in a direction perpendicular to a surface of the metal block 11, but the position of the through hole 11a is different between an outer face side and a joint face side (both are partly overlapped inside). A diameter d2 of the through hole 11a in a rectilinear portion which is common to both front and back faces of the respective metal blocks 111, 112 is about φ0.25 mm, which is the same as described in FIGS. 1A and 1B. Moreover, the outer diameter D1 of the contact probe 12GND for grounding and the inner diameter D2 of the through hole 11a are respectively about 0.3 mm and 0.35 mm, which are the same as described in FIGS. 1A and 1B.

Even in this structure, a difference between d2 and D1 is only about 0.05 mm in the same manner as in the embodiment as shown in FIGS. 1A and 1B, which has such a size that the contact probe 12GND for grounding can be meanderingly inserted when it is forcibly pushed in. Therefore, it is possible to insert the contact probe 12GND for grounding. In this embodiment, the swelled part at the center part of the metal block 11 is broad, and therefore, the contact probe 12GND for grounding is reliably contacted with the metal block 11 at both ends G (two positions) of the swelled part, and ends (discontinued parts) E, F of rectilinear parts of the through hole at both upper and lower sides of the metal block 11 thereby to secure the electrical connection.

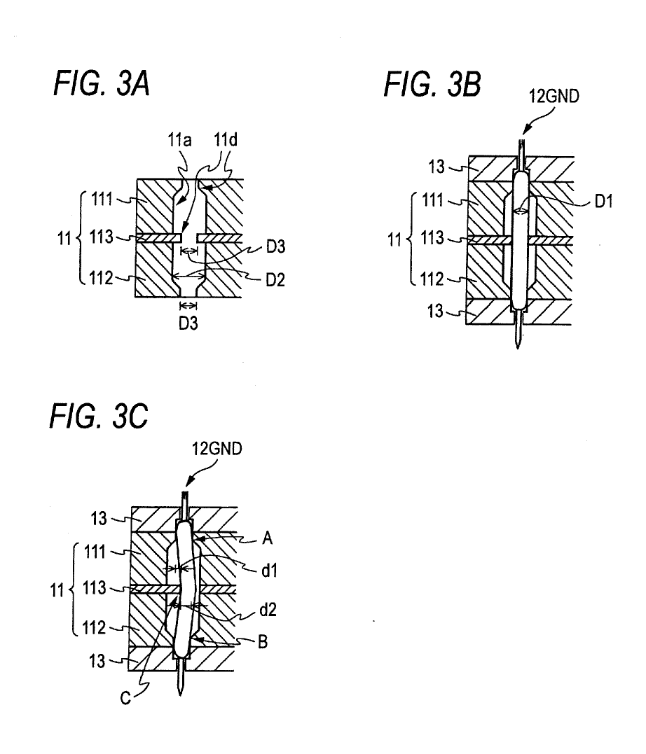

FIGS. 3A to 3C are explanatory sectional views showing process for producing the through hole 11a in the metal block 11 and the contact probe 12GND for grounding in still another embodiment of the invention. Specifically, in this embodiment, the metal block 11 is divided in three, into first, second and third metal blocks (a first layer, a second layer and a third layer) 111, 112, 113, and formed in a sandwich structure in which the third metal block 113 is sandwiched between the first and second metal blocks 111 and 112. After the contact probe 12GND for grounding has been inserted, the third metal block 113 which is an intermediate layer is displaced, whereby a bending stress is applied to the contact probe 12GND for grounding to achieve reliable contact.

In this embodiment, an inner diameter D3 of the through hole 11a in the third metal block 113 at a surface side of the first and second metal blocks 111, 112 is about φ0.35 mm (D3=φ0.35 mm), and an inner diameter D2 of the through hole 11a in the first and second metal blocks 111, 112 at sides adjacent to the third metal block 113 is about φ0.55 mm. This diameter D2 is equal to the inner diameter D2 of the through hole 11a, and can absorb a bent portion of the contact probe 12GND for grounding when it is deformed, by displacing the third metal block 113. In this structure too, an offset amount d1 after the contact probe 12GND for grounding has been bent by displacing the third metal block 113 is about 0.1 mm which is the same as in the embodiment as shown in FIGS. 1A and 1B, and a diameter d2 of a part rectilinearly connecting the surface of the first metal block 111 to a back face of the second metal block 112 is about φ0.25 mm which is the same as in the embodiment as shown in FIGS. 1A and 1B.

In this structure too, it is possible to attain reliable contact between the contact probe 12GND for grounding and the metal block 11 at discontinued points A, B where the inner diameter of through hole is enlarged inside the metal blocks 111, 112, and at a part C where the third metal block 113 is butted against the contact probe 12GND for grounding (a discontinued part) after the third metal block 113 has been displaced. The same parts as those in FIGS. 1A to 2C are denoted with the same reference numerals, and their description is omitted.

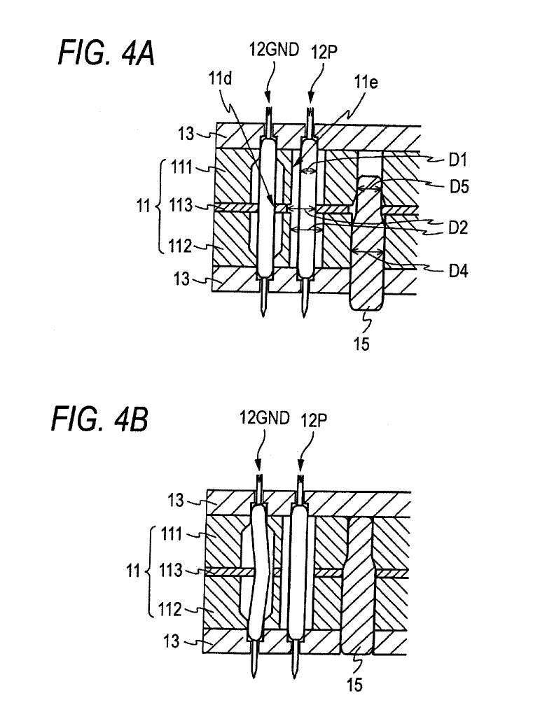

FIGS. 4A and 4B shows an example of a method of displacing the third metal block 113 in the embodiment as shown in FIGS. 3A to 3C. Specifically, a through hole 11d for allowing the contact probe 12GND for grounding to pass through is formed in advance in the third metal block 113, by offsetting about 0.1 mm from the original position. Then, as shown in FIG. 4A, the first, second, and third metal blocks 111, 112, 113 are superposed in such a manner that the through hole 11d which has been offset in the third metal block 113 may be aligned with a position of the contact probe 12GND for grounding. In this state, the contact probe 12GND for grounding and other contact probes 12 such as the contact probe 12P for power supply or other signals than RF signals are inserted. On this occasion, the diameter D2 of the through hole 11e in the third metal block 113 dealing with the contact probe 12P for power supply has the same size as the diameter D2 of the through hole 11e in the first and second metal blocks 111, 112 and is set to be about φ0.55 mm, for example. On the other hand, the positioning pin 15 is composed of a large diameter part having a large diameter D4 of about φ1 mm and a small diameter part having a small diameter D5 of about φ0.8 mm. The positioning pin 15 is inserted in such a manner that the small diameter part may be positioned in the third metal block 113. Specifically, the third metal block 113 is firmly positioned at the small diameter part of the positioning pin 15 where an offset amount of the through hole 11e for the contact probe 12P for power supply is largest, and the first and second metal blocks 111, 112 are firmly positioned by the positioning pin 15.

Thereafter, as shown in FIG. 4B, by pushing up the positioning pin 15 so that the large diameter part of the positioning pin 15 may be aligned with the third metal block 113, the third metal block 113 is displaced by about 0.1 mm (a half of a difference between the large diameter and the small diameter). Because the through hole 11d in the third metal block 113 dealing with the contact probe 12GND for grounding is offset, a center part of the contact probe 12GND for grounding is pressed and deformed. The through hole 11e for the contact probe 12P for power supply is rectilinearly connected through the first, second and third metal blocks 111, 112, 113. As the results, like shown in FIG. 3C, the metal block 11 and the contact probe 12GND for grounding come into reliably contact with each other at the points A, B and C, and reliable electrical connection can be obtained. On the other hand, the through holes 11e, namely the through holes in the metal blocks 111 and 112, are communicated with respect to the other contact probes 12 than the contact probe 12GND for grounding. Therefore, even with the contact probe for RF signals (not shown in FIGS. 4A and 4B), a correct size as the external conductor of the coaxial structure can be assured, and performance will not be deteriorated.

According to an aspect of the invention, a discontinued part is formed on the inner wall of the through hole in the metal block along the axial direction. Therefore, even though the contact probe for grounding is not covered with the ground tube, but directly inserted into the through hole in the metal block, the contact probe for grounding is deformed by the discontinued part of the through hole, and brought into reliable contact with the inner wall of the through hole in the metal block at both end sides of the contact probe for grounding which has been deformed in vicinity of the discontinued part and the discontinued part itself, whereby electrical connection can be secured. As the results, it is unnecessary to insert the ground tube into the contact probe for grounding, and thereafter, to insert the ground tube into the through hole in the metal block, and hence, the inspection socket can be very easily assembled. Accordingly, it is possible to provide the inspection socket at a very low cost, to reliably connect the grounding terminal of the object to be inspected to the ground, and to conduct a precise inspection in the same manner as in case of actual mounting.

Moreover, by employing the method in which the metal block is formed in three layers in the sandwich structure in which the third layer is sandwiched between the first layer and the second layer, and the third layer is displaced, after the contact probe for grounding has been inserted, the electrical connection can be easily obtained in vicinity of the discontinued part, without occurring such a problem that the discontinued part of the through hole makes it difficult to insert the contact probe for grounding.

In the above description, the metal block is not limited to an integral body of metal, but includes also a plurality of plate-like bodies of metal superposed and fixed. The contact probe means a probe in which a distal end of a lead wire (plunger) is movable along an axial direction, for example, in such a manner that the lead wire (plunger) is provided in a metal pipe by way of a spring so that one end of the plunger may be projected from the metal pipe, while the other end may not escape from the metal pipe, whereby when the one end of the plunger is pressed, the plunger is retracted to an end of the metal pipe, and when an outer force is released, the plunger is projected outward by a force of the spring. Moreover, the discontinued part means a part which is not rectilinear in the axial direction, because the inner wall is bent in a sectional view, or formed with a recess or a projection.

According to an aspect of the invention, the inspection socket can be utilized for precisely inspecting electrical performance of an object to be inspected in which electrode terminals are arranged at a very narrow pitch, such as a monolithic IC, a hybrid IC of an LSI (a large scale integrated circuit), or a module component in which desired functions are realized.

What is claimed is:

1. An inspection socket configured to connect an electrode terminal of an object to be inspected and a wiring of a wiring board, the inspection socket comprising:
a metal block including a first surface to be opposed to the object to be inspected and a second surface to be opposed to the wiring board, the metal block provided with a through hole connecting the first surface and the second surface in a first direction, an inner wall of the through hole having a part which is not rectilinear in the first direction; and
a contact probe for grounding provided in the through hole, the contact probe for grounding being connected to the inner wall of the through hole, at least in vicinity of the part which is not rectilinear.

2. The inspection socket according to claim 1, wherein
the contact probe for grounding is bent by the part which is not rectilinear, whereby the contact probe for grounding is directly and electrically connected to the inner wall of the through hole, at least in vicinity of the part which is not rectilinear.

3. The inspection socket according to claim 1, further comprising:
a securing member securing the contact probe for grounding so as not to escape from the through hole.

4. The inspection socket according to claim 1, wherein
the through hole is formed in an L-shape in a sectional view in the first direction.

5. The inspection socket according to claim 1, wherein
a center position of the through hole at one end on the first surface of the metal block and a center position of the through hole at an inside in the first direction are offset in a second direction perpendicular to the first direction.

6. The inspection socket according to claim 1, wherein
the metal block has a first layer, a second layer and a third layer which is disposed between the first layer and the second layer,
the first layer includes a first hole, the second layer includes a second hole and the third layer includes a third hole,
the through hole is defined by the first hole, the second hole and the third hole,
an inner diameter of the third hole is smaller than an inner diameter of the first hole and an inner diameter of the second hole, and
the third hole is offset from at least one of the second hole and the first hole.

7. A method of producing an inspection socket, the method comprising:
preparing a metal block having a first layer, a second layer and a third layer which is disposed between the first layer and the second layer, the first layer including a first hole, the second layer including a second hole, the third layer including a third hole, a through hole being defined by the first hole, the second hole and the third hole in a state where the first layer, the second layer and the third layer are superposed;
inserting a contact probe for grounding into the through hole; and
displacing the third layer so that the third hole is offset from at least one of the second hole and the first hole.

8. An inspection socket configured to connect an object to be inspected and a wiring board, the inspection socket comprising:
a metal block including a first surface to be opposed to the object to be inspected and a second surface to be opposed to the wiring board, the metal block provided with a through hole connecting the first surface and the second surface, an inner wall of the through hole having:
a first portion extending in a first direction;
a second portion extending in a second direction different from the first direction; and
a third portion connecting the first portion and the second portion; and
a contact probe for grounding provided in the through hole, a part of the contact probe being in contact with the third portion.
